(19) United States
(12) Patent Application Publication
(10) Pub. No.: US 2005/0282315 A1
(43) Pub. Date: Dec. 22, 2005

(54) High-reliability solder joint for printed circuit board and semiconductor package module using the same

(76) Inventors: Se-Young Jeong, Seoul (KR); Se-Yong Oh, Gyeonggi-do (KR)

Correspondence Address: MARGER JOHNSON & McCOLLOM, P.C., 1030 S.W. Morrison Street, Portland, OR, 97205, US

(21) Appl. No.: 11/148,547

(22) Filed: Jun. 8, 2005

(30) Foreign Application Priority Data
Jun. 8, 2004 (KR) 2004-41854

(51) Int. Cl. H01L 21/44

(52) U.S. Cl. 438/125

(57) ABSTRACT

A printed circuit board and a semiconductor package module using the same in which solder joint reliability (SJR) is improved. The printed circuit board includes: a first terminal exposed to the external of the printed circuit board in a print circuit pattern to be connected to a solder ball of a semiconductor package; a second terminal exposed to the external of the printed circuit board in the printed circuit pattern to be connected to another printed circuit board; and a buffer layer, which is an insulating layer formed adjacent the first terminal, being formed of a thermal absorption material, e.g. an elastomer, configured to absorb thermal stress caused by any difference of coefficients of thermal expansion between the semiconductor package and the first terminal, wherein the printed circuit board is a multi-layered printed circuit board including alternately layered insulators and printed circuit patterns.

### BACKGROUND OF THE INVENTION

This application claims the priority of Korean Patent Application No. 2004-41854, filed on Jun. 8, 2004, in the Korean Intellectual Property Office, the disclosure of which is incorporated herein in its entirety by reference.

### 1. FIELD OF THE INVENTION

This disclosure invention relates to a printed circuit board and a semiconductor package module using the same, and more particularly to stress problems caused by a difference in coefficients of thermal expansion between the semiconductor package and the printed circuit board.

### 2. DESCRIPTION OF THE RELATED ART

A wafer level package (WLP) in which a semiconductor package is assembled at a wafer level represents an important recent advance over plastic packages that use a conventional wire bonding process. In recent years, wafer level package applications include the mounting of plural wafer level packages-whether of the same circuit type or different circuit types-on a single printed circuit board to perform a desired function. Such WLP-mounted printed circuit boards typically provide electrical interfaces to other circuits via cables, wire harnesses or other printed circuit boards, e.g. motherboards, via patterned edge connectors.

FIG. 1 is a plan view illustrating a conventional semiconductor package module.

Referring to FIG. 1, in the semiconductor package module 50, a wafer level package 30 is mounted on one or more surfaces of a printed circuit board 40 by a solder bump or solder ball 10 (shown in FIG. 2). The solder bump or ball 10 is formed between the printed circuit board 40 and the wafer level package 30 and typically provides an electrical connection for a signal path therebetween. The printed circuit board 40 typically has a tap 20, e.g. one or more edge connectors each conveying one or more signals, that provides one or more connection terminals to an external cable or printed circuit board, e.g. a motherboard.

The reliability of the semiconductor package module 50 mounting one or more of the wafer level packages 30 is tested in various ways. One such test is a temperature cycling test. In the temperature cycling test, the semiconductor package module is repeatedly cycled over a temperature range of −55° C. and 125° C. for five or ten minutes. During the temperature cycling the inner state and behavior, i.e. the functionality, of the semiconductor package module, as a function of temperature, is evaluated.

However, in the semiconductor package module 50 a wafer level package 30a mounted near an edge of the printed circuit board 40 is subjected to thermal stress caused by a difference in the coefficients of thermal expansion between the semiconductor package 30 and the printed circuit board 40. Accordingly, defects manifest in the solder, e.g. in the solder bump or the solder ball 10, that connects the wafer level package 30 and the printed circuit board 40.

FIG. 2 is a sectional view taken along line II-II′ of FIG. 1. Those of skill in the art will appreciate that FIG. 2 (as well as FIG. 3) is a view of semiconductor package module 50 of FIG. 1 taken by rotating the top edge of module 50 in FIG. 1 outwardly ninety degrees and the bottom edge of module 50 in FIG. 1 inwardly ninety degrees. As may be seen from FIGS. 2 and 3, this rotation positions semiconductor chip 30a below, rather than above, printed circuit board 40.

Insulating layers 41, 43, 45 and 47 and print circuit patterns 42, 44 and 46 are alternately formed in the multi-layered printed circuit board 40. Further, a pad 42 for externally connecting with another printed circuit board and a pad 46 for externally attaching the solder bump or the solder ball 10 of the wafer level package 30 are formed on exposed surfaces of the printed circuit board 40.

A bond pad 31, a passivation layer 36, a bond-pad rearrangement pattern 33, and first and second insulating films 34 and 35 are formed on the semiconductor chip 32 of the wafer level package 30. The wafer level package 30 is physically and electrically attached to the printed circuit board 40 by the solder bump or the solder ball 10, which will be referred to herein as an external connection terminal of the wafer level package 30. Those of skill in the art will appreciate that a given wafer level package 30 includes at least one and typically more than one such electrical connection to various traces on printed circuit board 40, each typically in the form of the solder bump or the solder ball 10.

FIG. 3 is a sectional view illustrating a defect caused by temperature cycling of the conventional semiconductor package module.

When a reliability test such as temperature cycling is performed, a solder ball 10′ is subjected especially near an edge of the semiconductor package module to thermal stress caused by the difference in the coefficients of thermal expansion between the wafer level package 30 and the printed circuit board 40. Cracks 12 and 14 appear in the solder ball, typically near the surfaces of the wafer level package 30 and the printed circuit board 40, respectively.

In order to solve a problem of solder joint reliability (SJR) deterioration, U.S. Pat. No. 5,777,379 discloses that an elastomer can be used in a semiconductor package such as a ball grid array (BGA) to reduce stress concentrations on a solder ball. However, in U.S. Pat. No. 5,777,379, the occurrence of cracks such as crack 14 is prevented from appearing in the solder ball near the surface of the semiconductor package 30, while the occurrence of cracks such as crack 12 in the solder ball 10′ near the surface of the printed circuit board 40 continues unabated.

Consequently, and because of solder joint reliability (SJR) problems, the performance reliability of the conventional semiconductor package module remains compromised.

### SUMMARY

The present invention provides, among other things, a printed circuit board for a semiconductor package module in which solder joint reliability (SJR) is improved.

Also, the invention provides a semiconductor package module in which SJR is improved.

According to an aspect of the invention, there is provided a printed circuit board for a semiconductor package module, the printed circuit board including: a first terminal exposed to the external of the printed circuit board in a printed circuit pattern to be connected to a solder ball of a semiconductor package; a second terminal exposed to the external of the printed circuit board in a print circuit pattern to be connected to a cable, wiring harness or another printed circuit board, e.g. a motherboard; and a buffer layer, which is an insulating layer formed adjacent the first terminal, being formed of a thermal absorption material, e.g. an elastomer, configured to absorb thermal stress caused by any difference in coefficients of thermal expansion between the semiconductor package and the first terminal, wherein the printed circuit board is a multi-layered printed circuit board including alternately layered insulators and printed circuit patterns.

The buffer layer is formed adjacent the first terminal and has a combined material structure of elastomer and metal.

According to another aspect of the invention, there is provided a semiconductor package module for improving solder joint reliability (SJR), the module including: a printed circuit board including a multi-layer structure, and having a first terminal that can mount a semiconductor package, and including a second terminal that can be connected to a motherboard; a buffer layer being formed of a photosensitive material adjacent the first terminal of the printed circuit board, thereby to absorb thermal stress caused by any difference in the coefficients of thermal expansion of the semiconductor package and the printed circuit board; and a semiconductor package mounted on the printed circuit board through the first terminal.

The semiconductor package, which is a wafer level package (WLP), includes a structure, e.g. a three-dimensional pillar-shaped under-bump-metal (UMB) structure, that is formed on an input/output pad in contact with the solder ball, which solder ball is connected in turn to the first terminal of the printed circuit board, thereby to absorb thermal stress caused by the different coefficients of thermal expansion.

According to the invention, the printed circuit board has the buffer layer adjacent the first terminal connected with the solder ball, and the semiconductor package has the three-dimensional pillar-shaped UBM formed on the input/output pad connected with the solder ball so that the solder joint reliability (SJR) of the semiconductor package module is improved against the stress concentrated in the solder ball caused by the differential coefficients of thermal expansion of the printed circuit board and the semiconductor package.

### BRIEF DESCRIPTION OF THE DRAWINGS

The above and other features and advantages of the invention will become more apparent by describing in detail exemplary embodiments thereof with reference to the attached drawings.

FIG. 1 is a plan view illustrating a conventional semiconductor package module.

FIG. 2 is a sectional view taken along the line II-II′ of FIG. 1.

FIG. 3 is a sectional view illustrating defects generated when a temperature cycling test is performed using a conventional semiconductor package module.

FIG. 4 is a sectional view illustrating a printed circuit board for improving a solder joint reliability (SJR) according to one embodiment of the invention.

FIGS. 5 through 9 are sectional views illustrating a method of manufacturing the printed circuit board of FIG. 4.

FIG. 10 is a sectional view illustrating an alternative embodiment of the buffer layer of a printed circuit board according to another embodiment of the invention.

FIG. 11 is a partial sectional view illustrating a semiconductor package module for improving a solder joint reliability (SJR) according to yet another embodiment of the invention.

FIGS. 12 through 15 are sectional views illustrating a method of manufacturing a three-dimension pillar-shaped under-bump-metal (UBM) structure formed on an input/output pad of a semiconductor package in a semiconductor package module according to a still another embodiment of the invention.

### DETAILED DESCRIPTION

The invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete and will fully convey the concept of the invention to those skilled in the art.

FIG. 4 is a sectional view illustrating a printed circuit board for improving solder joint reliability (SJR) according to one embodiment of the invention.

A printed circuit board 100 to improve the SJR is a multi-layered printed circuit board where insulating layers 102, 106 and 116 and print circuit patterns 103, 108 and 114 are alternately layered. The printed circuit board 100 has a first terminal 118 exposed externally of the printed circuit board in a printed circuit pattern to be connected with a solder ball of a semiconductor package. Further, the printed circuit board 100 has a second terminal 120 exposed externally of the printed circuit board in the printed circuit pattern to be connected with another printed circuit board.

Further, the printed circuit board 100 includes a buffer layer 110, which is an insulating layer formed vertically adjacent the first terminal 118, formed of an elastomer (e.g. a photosensitive material) 1 to absorb thermal stress caused by any difference in coefficients of thermal expansion between the semiconductor package and the first terminal 118.

In accordance with one embodiment of the invention, the buffer layer 110 is formed of an elastomer to absorb thermal stress that might be concentrated on the vertically adjacent solder ball. Since the buffer layer 110 is formed of a photosensitive elastomeric material, it is particularly advantageous to form the buffer layer 110 at least in the vicinity of the first terminal 118. Alternatively, however, the buffer layer 110 can be formed on the entire surface of the printed circuit board 100, since that too will relieve thermal stress occasioned by thermally cycling the semiconductor package module.

Accordingly, the buffer layer 110 is formed of an elastomeric material, in contrast to a material that is unable to absorb thermal stress, e.g. conventional photo solder resist (PSR) material that typifies other insulating films 102, 106 and 116. The buffer layer 110 can absorb the thermal stress of temperature cycling, thereby preventing a crack defect from occurring in the solder ball when the stress is concentrated on the solder ball during the temperature cycling performance reliability test.

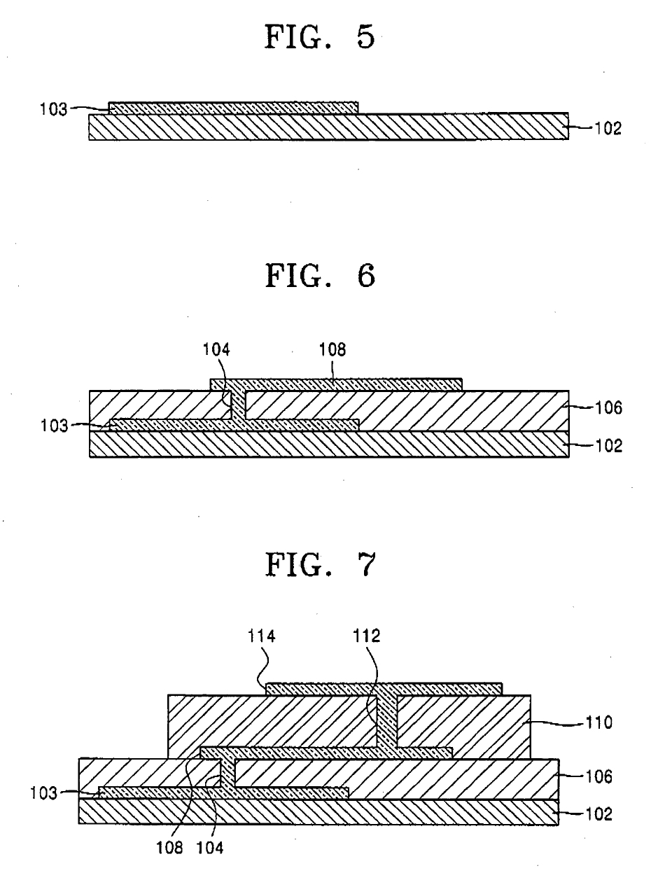

The printed circuit board 100 including the buffer layer 110 can be manufactured using various methods, within the spirit and scope of the invention, but one example of a manufacture method is described with reference to FIGS. 5 through 9.

First, a first photo solder resist (PSR) layer 102 is formed, and a first printed circuit pattern 103 is formed on the first PSR layer 102 using any suitable method. Next, a second PSR layer 106 is formed on the resultant structure. Then, a photolithographic etch is performed to form a first via hole 104 to expose a portion of the first printed circuit pattern 103. Next, a plating process is performed to fill the via hole 104 with a conductive layer and a second printed circuit pattern 108 is formed, by any suitable method, the second printed circuit pattern 108 being connected with the conductive layer. These steps are illustrated in FIGS. 5 and 6.

FIG. 7 shows that an insulating material, e.g. an elastomer layer exhibiting photosensitivity, is used to form the buffer layer 110 on the second PSR layer 106 including the second printed circuit pattern 108. After that, a second via hole 112 is formed to expose the second print circuit pattern 108. Next, the second via hole 112 is filled with the conductive layer via any suitable plating process. Then a third printed circuit pattern 114 is formed on the buffer layer 110, the third printed circuit pattern 114 being connected with the conductive layer.

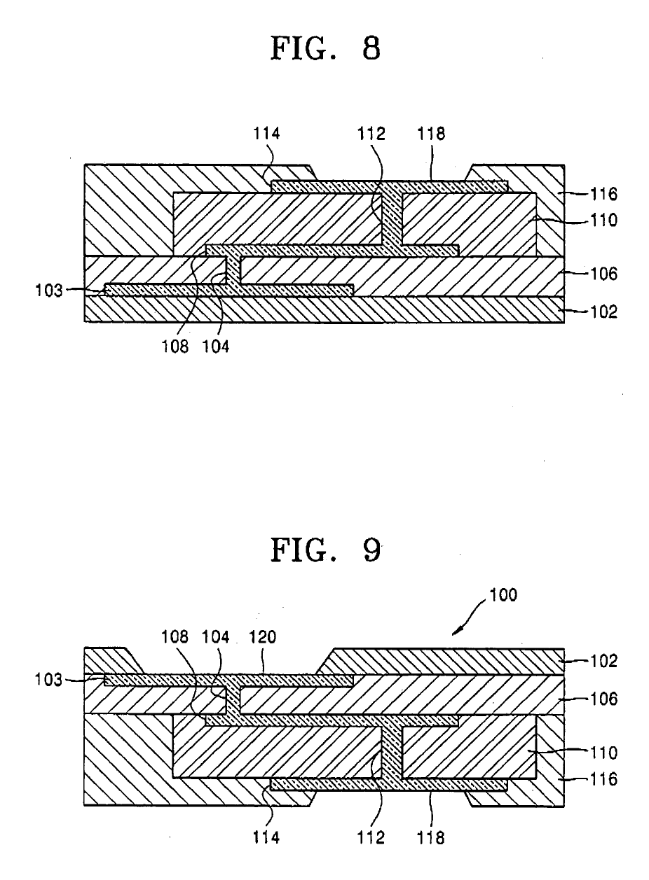

Referring to FIG. 8, a third PSR layer 116 is formed on the buffer layer 110 including the third printed circuit pattern 114, and a photolithography process is performed to form the first terminal 118 to expose a portion of the third printed circuit pattern 114. Those of skill in the art will appreciate that a solder ball (not shown in FIG. 8 or 9) of the semiconductor package can be attached to the first terminal 118.

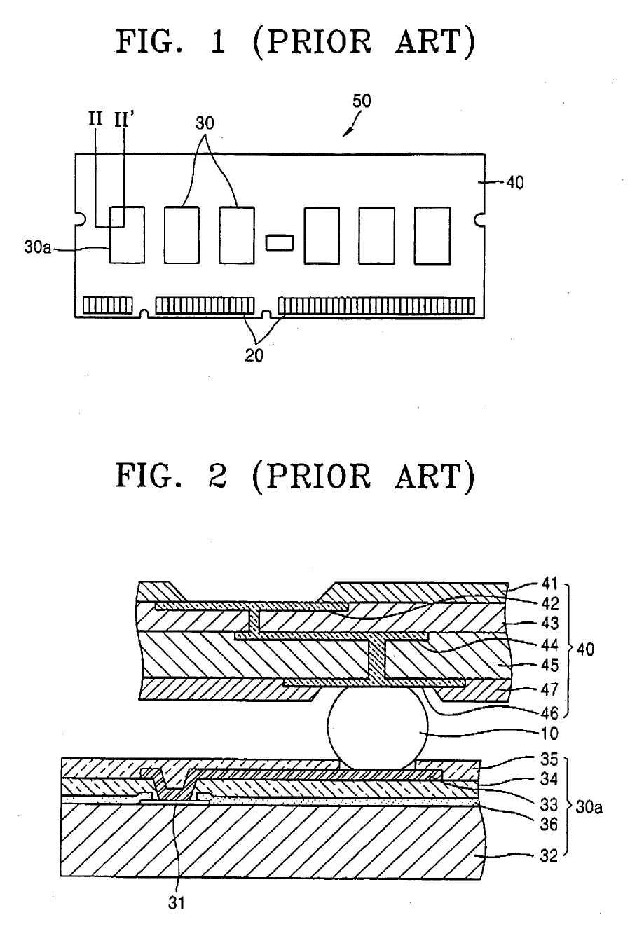

FIG. 9 shows the overall structure of FIG. 8 inverted to perform a photolithography process whereby a patterned portion of the first PSR layer 102 is removed to expose a portion of the first print circuit pattern 103, i.e. to form a second terminal 120. Those of skill in the art will appreciate that another solder ball can be attached to the second terminal 120. The second terminal 120 can be also patterned to form a tap (20 of FIG. 1) for external, e.g. motherboard, connections.

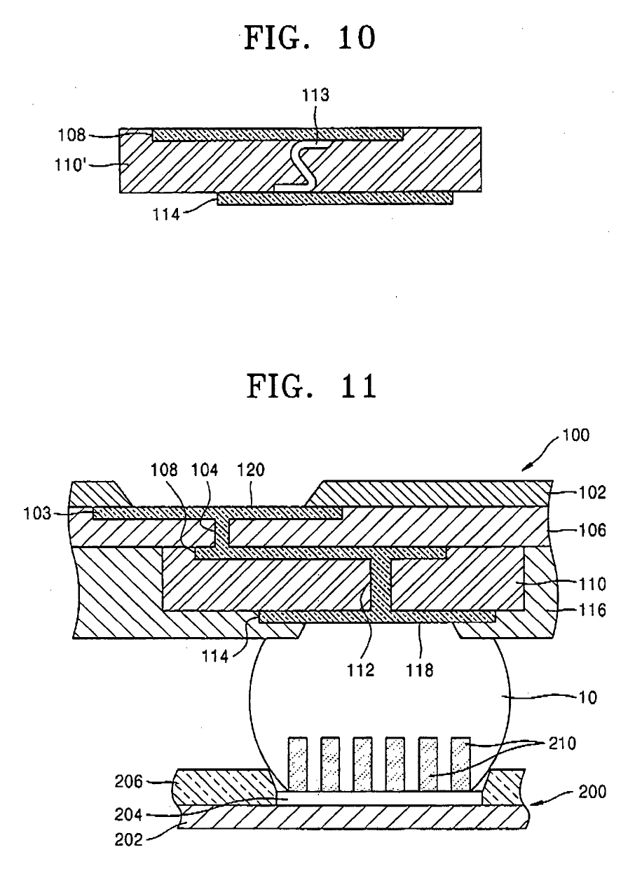

FIG. 10 is a sectional view illustrating an alternative example of the buffer layer 110'of the printed circuit board according to a preferred embodiment of the invention. An alternative to filling the via hole with a conductive material is proposed. The printed circuit patterns can be connected using a lifted lead 113 formed of a flexible conductive material that extends between and electrically connects printed circuit patterns 108 and 114 through the buffer layer 110′. Accordingly, the buffer layer 110′ in this embodiment is a material combination of elastomer and metal.

FIG. 11 is a partial sectional view illustrating the semiconductor package module for improving the solder joint reliability (SJR) according to a preferred embodiment of the invention.

The semiconductor package module includes the printed circuit board 100 including a multi-layered structure and including the first terminal 118 on which the semiconductor package can be mounted and the second terminal 120 to which a motherboard can be connected; the buffer layer 110 being formed of photosensitive material and being located adjacent the first terminal 118 of the printed circuit board that absorbs the thermal stress caused by a difference in coefficients of thermal expansion between the semiconductor package 200 and the first terminal 118 of the printed circuit board; and the semiconductor package 200 mounted on the printed circuit board 100 through the first terminal 118.

The semiconductor package 200 (a wafer level package (WLP), is connected to the first terminal 118 of the printed circuit board 100 through a solder bump or a solder ball 10. The semiconductor package 200 can further include a structure to absorb the thermal stress caused by differential coefficients of thermal expansion between the semiconductor package 200 and the printed circuit board 100 on an input/output (I/O) pad 204 to which the solder bump or the solder ball 10 is attached. The structure to absorb the thermal stress caused by differential coefficients of thermal expansion, which is a three-dimensional pillar-shaped under-bump-metal (UBM) 210, prevents a crack from appearing in the solder ball near the semiconductor package 200.

In FIG. 11, reference numeral 202 denotes a semiconductor chip, and reference numeral 206 denotes a passivation layer.

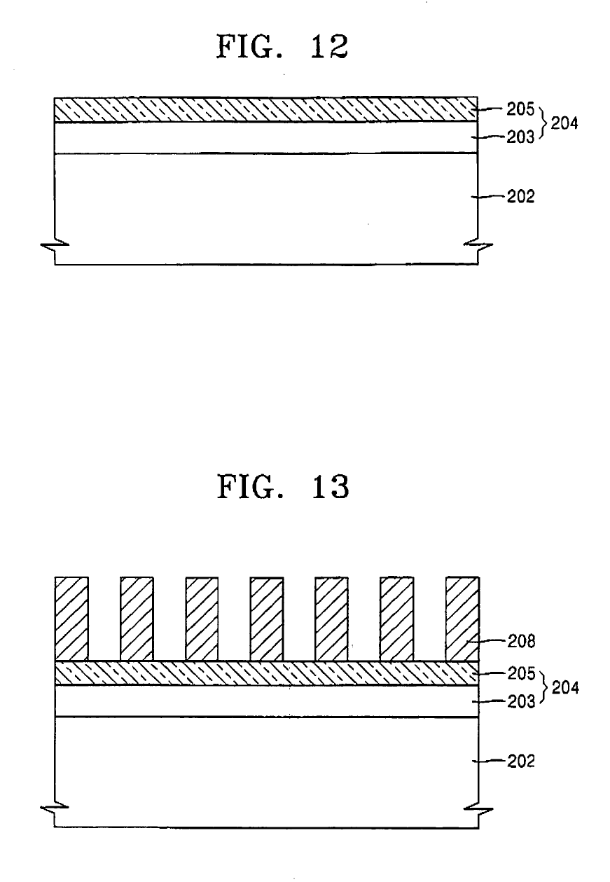

FIGS. 12 through 15 are sectional views illustrating a method of manufacturing the three-dimensional pillar-shaped under-bump-metal (UBM) formed on the I/O pad of the semiconductor package in the semiconductor package module, according to a preferred embodiment of the invention.

First, a seed layer 205 to be used in the plating process is formed on an I/O terminal 203 of the semiconductor chip 202 by a sputtering method. The seed layer 205 can be formed using a single film or a multi-layered film comprised of one selected from the groups consisting of titanium (Ti), nickel (Ni), copper (Cu), chrome (Cr), and aluminum (Al). Next, a photoresist pattern 208 is provided selectively to form the three-dimensional pillar-shaped UBM over the seed layer 205. This is shown in FIGS. 12 and 13.

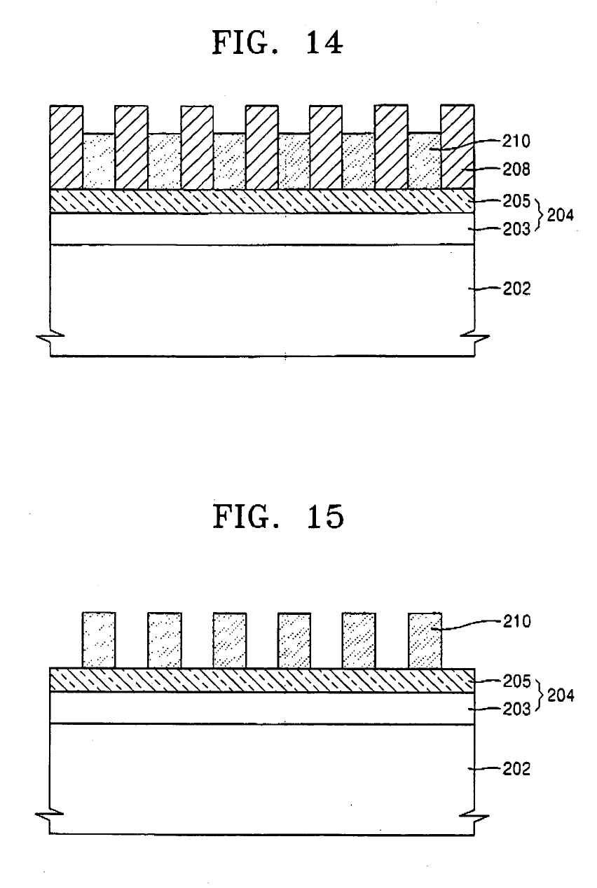

Electrical plating grows a selective conductive layer to form the three-dimension pillar-shaped UBM 210 only on the seed layer-exposed portions between sections of the photoresist pattern 208. This is shown in FIG. 14.

After the three-dimensional pillar-shaped UBM 210 is completely grown, the photoresist pattern 208 is removed so that only the three-dimensional pillar-shaped UBM 210 remains on the I/O pad 204. The three-dimension pillar-shaped UBM 210 can be formed from a material selected from the group consisting of silver (Ag), gold (Au), copper (Cu), and nickel (Ni), or a combination thereof. This is shown in FIG. 15.

Those of skill in the art will appreciate that the three-dimensional pillar-shaped UBM structure extends into the solder bump or the solder ball 10 and acts near the base of the ball to reinforce the ball structure to resist cracking from thermal stress caused by differential coefficients of thermal expansion between the semiconductor package 200 and the printed circuit board 100. Effectively, the three-dimensional UBM “comb” acts as a thermal shock absorber to spatially distribute the thermal stress over a wider, three-dimensional volume within the solder ball region near the semiconductor package 200. Thus thermal stress is reduced in this region that heretofore has been prone to cracking or other solder bump or solder ball defects.

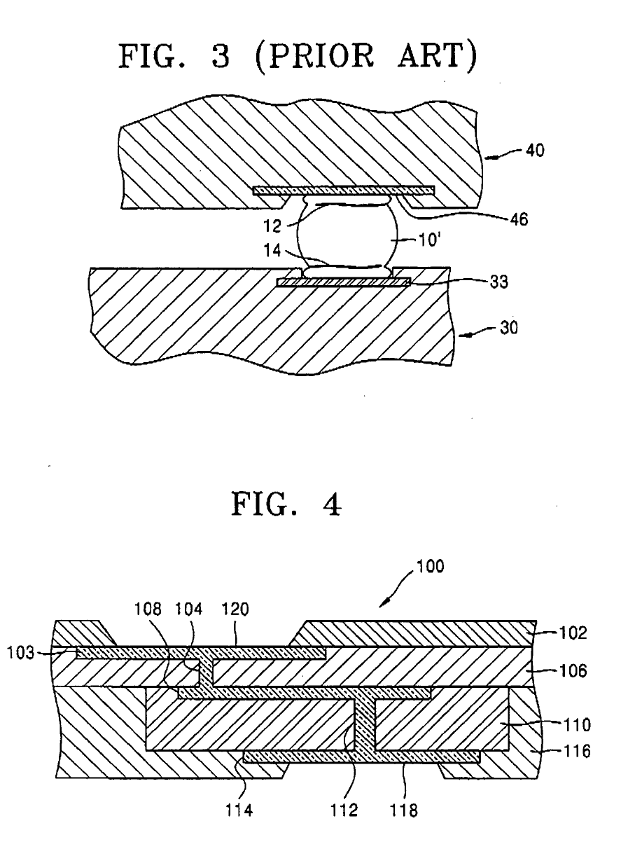

Accordingly, when the thermal stress is caused by a potentially differential coefficient of thermal expansion within a temperature cycling test chamber, the three-dimension pillar-shaped UBM 210 nevertheless prevents even the crack 12 (see FIG. 3) from appearing in the solder ball near the surface of the semiconductor package.

As described above, the printed circuit board has the buffer layer formed adjacent the first terminal connected with the solder ball, and the semiconductor package has the three-dimension pillar-shaped UBM formed on the I/O pad connected with the solder ball. As a result, the solder joint reliability (SJR) of a semiconductor package module can be improved against the stress concentrated on the solder ball by differential coefficients of thermal expansion between the printed circuit board and the semiconductor package.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor package module comprising:
a printed circuit board including a multi-layer structure, a first terminal on which a semiconductor package is mounted, and a second terminal connectable to an external electrical structure; and
a buffer layer formed of a thermal absorption material adjacent the first terminal of the printed circuit board, thereby to absorb a thermal stress caused by any difference in coefficients of thermal expansion between the semiconductor package and the printed circuit board.

2. The module of claim 1, further comprising a semiconductor package mounted on the printed circuit board through the first terminal.

3. The module of claim 1, wherein the buffer layer includes a photosensitive material.

4. The module of claim 1, wherein the buffer layer includes an elastomer.

5. The module of claim 1, wherein the buffer layer has includes an elastomer and a metal.

6. The module of claim 1, wherein the buffer layer is formed at least in part adjacent the first terminal.

7. The module of claim 1, wherein the second terminal includes a conductive ball pad in the printed circuit board.

8. The module of claim 1, wherein the semiconductor package is mounted vertically adjacent the first terminal of the printed circuit board by a solder ball or a solder bump.

9. The module of claim 1, wherein the semiconductor package is a wafer level package (WLP).

10. The module of claim 9, wherein the wafer level package includes a structure that is formed on an input/output pad in contact with the solder ball, the solder ball being connected to the first terminal of the printed circuit board, the structure being configured to absorb thermal stress caused by any differential coefficients of thermal expansion.

11. The module of claim 10, wherein the structure formed on the input/output pad is a three-dimensional pillar-shaped under-bump-metal (UBM).

12. The module of claim 11, wherein the three-dimensional pillar-shaped UBM is formed of a material selected from the group consisting of silver (Ag), gold (Au), copper (Cu), and nickel (Ni).

13. The module of claim 11, wherein the three-dimensional pillar-shaped UBM is formed of a combination of one or more materials selected from the group consisting of silver (Ag), gold (Au), copper (Cu), and nickel (Ni).

14. A printed circuit board for a semiconductor package module, the printed circuit board comprising:
an exposed first terminal of the printed circuit board connectable to a solder ball of a semiconductor package;
an exposed second terminal of the printed circuit board connectable to a cable, a wire harness, or another printed circuit board; and
a buffer layer formed of a thermal absorption material configured to absorb thermal stress caused by any difference in coefficients of thermal expansion between the semiconductor package and the first terminal,
wherein the printed circuit board is a multi-layered printed circuit board including an alternately layered plurality of insulators and printed circuit patterns.

15. The printed circuit board of claim 14, wherein the buffer layer is formed of a photosensitive material.

16. The printed circuit board of claim 14, wherein the buffer layer is formed of an elastomer.

17. The printed circuit board of claim 14, wherein the buffer layer includes an elastomer and a metal.

18. The printed circuit board of claim 14, wherein the buffer layer is formed at lest partially adjacent the first terminal.

19. A method of manufacturing a semiconductor package module, comprising:
forming a first photo solder resist layer;
forming a first printed circuit pattern on the first photo solder resist layer;
forming a second photo solder resist layer on the first photo solder resist layer that includes the first printed circuit pattern;
etching the second photo resist layer to form a first via hole that exposes a portion of the first printed circuit pattern;
filling the first via hole with a first conductive layer;
forming a second printed circuit pattern electrically connected with the first conductive layer;
forming a buffer layer of an elastomeric insulating material on the second photo solder resist layer that includes the second printed circuit pattern;
etching the buffer layer to form a second via hole that exposes the second printed circuit pattern;
filling the second via hole with a second conductive layer;
forming a third printed circuit pattern on the buffer layer electrically connected with the second conductive layer;
forming a third photo solder resist layer on the buffer layer that includes the third printed circuit pattern; and
etching the third photo solder resist layer to form a first terminal that exposes a portion of the third printed circuit pattern.

20. The method of claim 19, which further comprises:
providing one or more semiconductor packages;
inverting one or more semiconductor packages; and for each of the one or more semiconductor packages
etching the first photo solder resist layer to form a second terminal that exposes a portion of the first printed circuit pattern.

21. The method of claim 20, which further comprises:
forming a printed circuit board including one or more second terminals; and
mounting one or more semiconductor packages on the printed circuit board by affixing one or more solder bumps or solder balls between the one or more first terminals and the one or more corresponding second terminals.
